(19) United States
(12) Patent Application Publication
(10) Pub. No.: US 2003/0006487 A1
(43) Pub. Date: Jan. 9, 2003

(54) Semiconductor device having element isolation structure

(75) Inventor: Tsuyoshi Sugihara, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/189,587

(22) Filed: Jul. 8, 2002

(30) Foreign Application Priority Data
Jul. 9, 2001 (JP) 2001-207405(P)

(51) Int. Cl. H01L 23/58

(52) U.S. Cl. 257/649

(57) ABSTRACT

An element isolation structure of a semiconductor device that prevents travel of ions through an isolation film at the time of ion implantation during an element formation step, and also prevents break of the isolation film in the event of misalignment of a contact hole during an interconnection formation step are provided. The semiconductor device includes an isolation film formed on a main surface of a silicon substrate, and a protective nitride film formed on the isolation film. An upper surface of the isolation film is higher in level than the main surface of the silicon substrate. The protective nitride film is positioned, as seen from above, inner than a portion of the isolation film exposed on the main surface of the silicon substrate.

### BACKGROUND OF THE INVENTION

1. Field of the Invention

The present invention relates to a semiconductor device having an element isolation structure, such as a flash memory.

2. Description of the Background Art

Conventionally, as an element isolation structure of a semiconductor device, an isolation film employing a trench as in STI (Shallow Trench Isolation), and an isolation film formed by LOCOS (Local Oxidation of Silicon) are known. Hereinafter, the way of forming such isolation films will be described in brief.

FIGS. 8A-8F are cross sectional views illustrating a manufacturing method of a semiconductor device employing the trench isolation technique. In this method, first, a pad oxide film (SiO₂) 2, a polycrystalline silicon (hereinafter, polysilicon) layer 3, and a silicon nitride film (Si₃N₄) 4 are deposited successively on a surface of a semiconductor substrate or silicon substrate 1 (FIG. 8A). Silicon nitride film 4, polysilicon layer 3 and pad oxide film 2 on an inactive region are removed to form a trench in silicon substrate 1 (FIG. 8B). A thin silicon oxide film 5 is then formed on a surface of the trench (FIG. 8C), followed by formation of a buried oxide film 6 to fill and cover the trench (FIG. 8D). Thereafter, CMP (Chemical Mechanical Polishing) is conducted, until the surface of silicon nitride film 4 on the active region is exposed, for surface planarization (FIG. 8E). The remaining silicon nitride film 4, polysilicon layer 3 and pad oxide film 2 are then removed, so that formation of the isolation film is completed (FIG. 8F).

FIGS. 9A-9D are cross sectional views illustrating a manufacturing method of a semiconductor device employing LOCOS to provide the isolation structure. In this method, first, pad oxide film 2 and silicon nitride film 4 are deposited successively on the surface of silicon substrate 1 (FIG. 9A). Silicon nitride film 4 is then removed, leaving that on the active region (FIG. 9B), and a thick field oxide film 9 for isolation is grown by thermal oxidation (FIG. 9C). Thereafter, silicon nitride film 4 and pad oxide film 2 are removed. Thus, the isolation film is formed (FIG. 9D).

After provision of the isolation structure by the trench isolation or LOCOS according to the procedures described above, an element structure is formed in the active region. In a succeeding interconnection step, an interlayer insulating film is formed on the surface of the silicon substrate. A prescribed portion of this interlayer insulating film is then etched and filled with an electric conductor, such as aluminum, to form an element electrode.

In recent semiconductor devices, the trench isolation has become common, since it is superior to LOCOS in surface planarization and in element isolating capability.

With the semiconductor device having an isolation film formed by the trench isolation or LOCOS as above, however, there are various kinds of constraints in the shape of the isolation film and the formation step thereof to allow the semiconductor device to acquire effective element isolation properties.

For example, if the isolation film is too thin, at the time of ion implantation during the subsequent step of forming an element like a source/drain, ions will travel through the isolating film to reach the silicon substrate beneath the isolating film, hindering achievement of effective element isolation properties. A conceivable way of preventing the ions from reaching the silicon substrate will be to restrict ion implantation energy low. It however leads to insufficient ion implantation, so that the semiconductor device as a whole would not be able to obtain effective element properties. It means that a thicker isolation film is more preferable to prevent the ions from travelling through the isolation film to reach the underlying semiconductor substrate during the ion implantation.

On the contrary, if the isolation film is too thick, the silicon substrate will be etched excessively during the element formation step. Specifically, at the time of simultaneously etching the surface of the semiconductor substrate and the isolation film, there is a high possibility that the surface of the semiconductor substrate is etched more than required. It means that a thinner isolation film is more preferable for ease of processing thereof. The control of the thickness of the isolation region was thus extremely difficult.

In addition, in the case of the trench isolation, the sidewall constituting the trench is steep, so that, if there occurs misalignment of a contact hole at the interconnection step following the element formation step, the contact and the silicon substrate may be short-circuited. Hereinafter, this problem will. be described in detail with reference to FIG. 10.

In the interconnection step following the element formation step, an interlayer insulating film 12 is formed to cover the entire surface of silicon substrate 1. A contact hole is formed in interlayer insulating film 12 by etching, utilizing photolithography. The contact hole is filled with a conductive material, such as aluminum, so that an element electrode 13 for electrical extraction of a source/drain is formed. Generally, when forming the contact hole by etching, interlayer insulating film 12 is over etched in consideration of variation in thickness thereof. This is to prevent loose connection even when the contact hole is being formed in the thick portion of interlayer insulating film 12.

However, if the contact hole reaches the isolation film due to misalignment, the isolation film will be etched away and broken, resulting in degradation of the reliability of the semiconductor device. Moreover, if the misalignment occurs by a distance indicated by an arrow A in FIG. 10, the contact hole will penetrate through the isolation film to reach the silicon substrate 1 beneath the isolation film, causing short-circuit.

Japanese Patent Laying-Open No. 10-308448 discloses an element isolation structure of a semiconductor device attempting to prevent break of the isolation film due to such misalignment of the contact hole. With the element isolation structure proposed therein, a field oxide film as an isolation film is formed by LOCOS, on which nitrogen ions are implanted, using as a mask the same nitride film used when forming the field oxide film, to nitride the upper portion of the field oxide film. This nitrided portion of the field oxide film protects the isolation film from break, even in the occurrence of the misalignment of the contact hole.

With this structure, however, the nitrogen ions introduced to the upper portion of the field oxide film may reach a portion beneath the nitride film as the mask, in which case the nitrided portion will be formed outer than the Bird's beak portion of the upper surface of the isolation film. Thus, in the semiconductor device such as a flash memory wherein a gate electrode is being formed adjacent to this nitrided portion, the gate electrode and the nitrided portion become too close to each other. This causes trapping of electrons to the nitrided portion, hindering assurance of good element properties. A complete solution to the foregoing problems has yet to be found.

### SUMMARY OF THE INVENTION

An object of the present invention is to provide an element isolation structure of a semiconductor device that eliminates the necessity of conventionally required control of the thickness of an isolation film, and that restricts an adverse effect of misalignment of a contact hole on element properties. Another object of the present invention is to provide an element isolation structure of a semiconductor device that prevents trapping of electrons from a gate electrode to a nitride film even when the isolation film is formed by LOCOS.

The element isolation structure of a semiconductor device according to an aspect of the present invention includes an element isolation region formed at a main surface of a semiconductor substrate, and a silicon nitride film formed on the element isolation region. The element isolation region has an upper surface protruding above the main surface of the semiconductor substrate. As seen from above, the silicon nitride film is positioned inner than a portion of the element isolation region exposed on the main surface of the semiconductor substrate.

With this structure, the silicon nitride film is formed on the isolation film as the element isolation region. Thus, at the time of ion implantation during the element formation step, the ions are prevented from travelling through the isolation film to reach the semiconductor substrate beneath the isolation film. Further, even when misalignment of a contact hole occurs in the interconnection step, the silicon nitride film protects the isolation film, so that short-circuit due to such misalignment of the contact is prevented, leading to an improved yield. In addition, the silicon nitride film is positioned higher in level than the main surface of the semiconductor substrate, and as seen from above, inner than the isolation film. Therefore, a certain distance is assured between the gate electrode and the silicon nitride film, which prevents trapping of the electrons.

Preferably, the element isolation region is formed to fill a trench provided in the semiconductor substrate at its main surface, and, as seen from above, the silicon nitride film is positioned to cover an area of the semiconductor substrate forming the bottom surface of the trench.

Preferably, the silicon nitride film overlaps an element region formed adjacent to the element isolation region, as seen from above.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view of the element isolation structure of a semiconductor device according to a first embodiment of the present invention.

FIG. 2 is a cross sectional view illustrating an effect of preventing a contact from reaching the bottom of a trench, accomplished by the element isolation structure of a semiconductor device according to the first embodiment.

FIGS. 3A-3H are cross sectional views illustrating the procedure of forming the element isolation structure of a semiconductor device according to the first embodiment.

FIG. 4 is a cross sectional view illustrating the element isolation structure of a semiconductor device according to a second embodiment of the present invention.

FIGS. 5A-5H are cross sectional views illustrating the procedure of forming the element isolation structure of a semiconductor device according to the second embodiment.

FIG. 6 is a cross sectional view illustrating the element isolation structure of a semiconductor device according to a third embodiment of the present invention.

FIGS. 7A-7G are cross sectional views illustrating the procedure of forming the element isolation structure of a semiconductor device according to the third embodiment.

FIGS. 8A-8F are cross sectional views illustrating the procedure of forming the element isolation structure of a semiconductor device employing conventional trench isolation.

FIGS. 9A-9D are cross sectional views illustrating the procedure of forming the element isolation structure of a semiconductor device effecting the element isolation by conventional LOCOS.

FIG. 10 is a cross sectional view illustrating the problem of misalignment of a contact hole in a semiconductor device having the conventional trench isolation structure.

### DESCRIPTION OF THE PREFERRED EMBODIMENTS

Hereinafter, the element isolation structures of semiconductor devices according to the embodiments of the present invention will be described with reference to the drawings.

First Embodiment

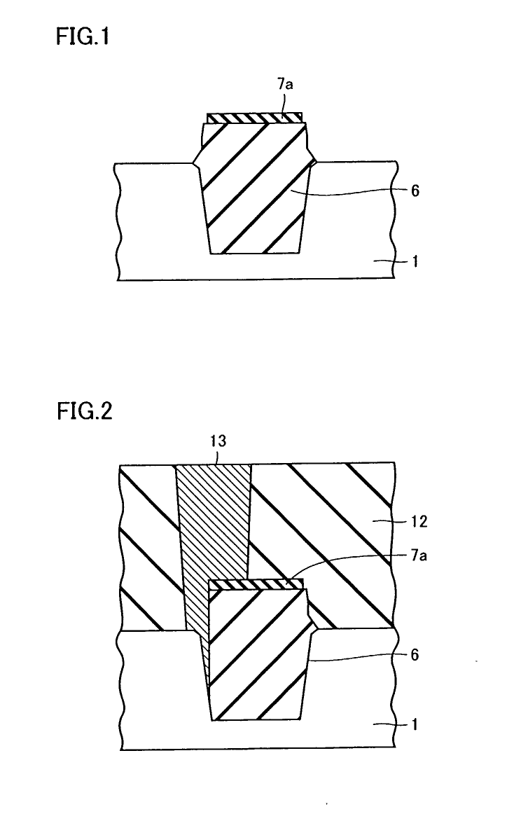

First, referring to FIG. 1, the element isolation structure of the present embodiment will be described. The isolation film of the present embodiment is formed by trench isolation. Specifically, a trench is formed at the surface of a silicon substrate 1 and filled with a buried oxide film 6, so that an isolation film 6 serving as the element isolation region is formed. During the formation of isolation film 6, a polysilicon layer 3 is formed on the surface of silicon substrate 1, and therefore, isolation film 6 protrudes above the surface of silicon substrate 1. A protective nitride film 7a is formed on isolation film 6, with a surface area slightly smaller than an upper, flat surface of buried oxide film 6.

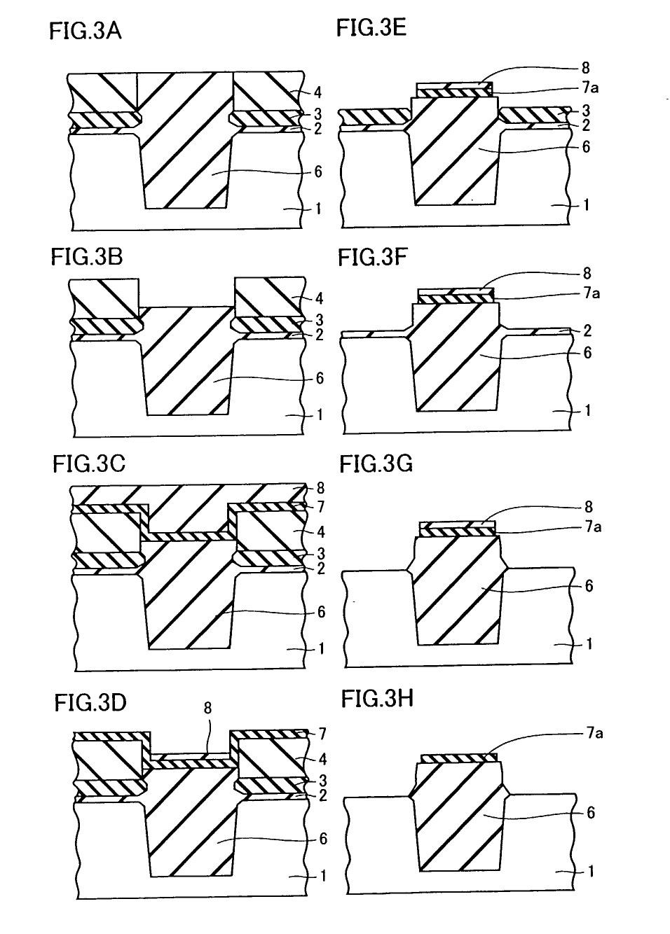

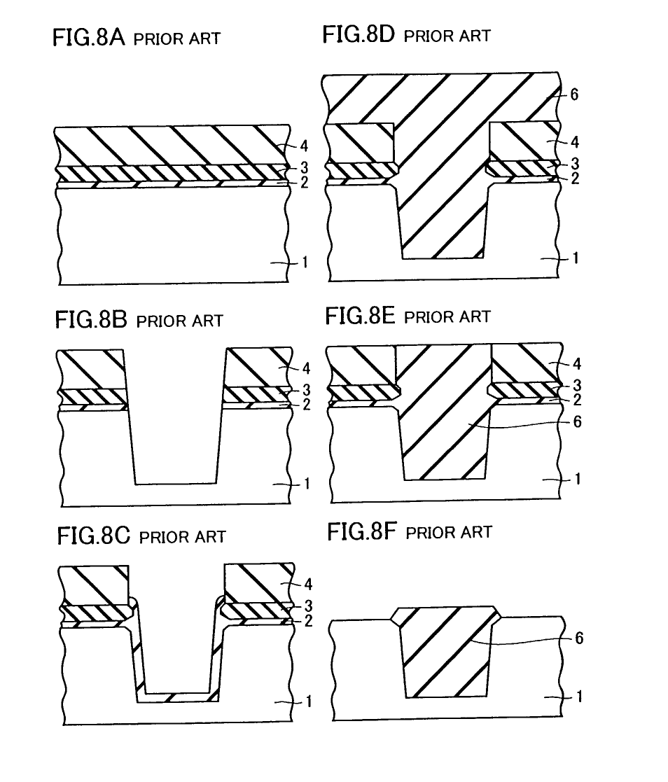

The manufacturing method of the semiconductor device having such isolation film and protective nitride film will now be described with reference to FIGS. 3A-3H. In this method, the trench is formed employing the conventional technique as described above, and thus, description of the respective steps up to the step shown in FIG. 8E, or FIG. 3A, is not repeated.

From the state shown in FIG. 3A, buried oxide film 6 is etched to a horizontal level higher than that of polysilicon layer 3, using an etching liquid or gas that can etch an oxide film selectively (FIG. 3B). Here, the etching liquid or gas enabling selective etching of the oxide film is defined as the one that can etch an oxide film faster than a nitride film. In this case, either dry etching or wet etching may be employed.

A nitride film 7 is then formed on the semiconductor surface, followed by deposition of an oxide-type film 8 thereon (FIG. 3C). Here, all that is needed is that oxide-type film 8 of at least a certain thickness is formed to cover a bottom surface of a recess formed of nitride film 7 on the semiconductor surface. The oxide-type film 8 may be formed by high-concentration plasma CVD (chemical vapor deposition), TEOS (tetraethoxysilane), or any other film formation technique. At this time, heat treatment may be added where appropriate. Further, CMP may be effected for planarization of oxide-type film 8, or SOG (Spin On Glass) may be performed for heat treatment.

Oxide-type film 8 is then etched away, using an etching liquid or gas enabling selective etching of the oxide film, to leave oxide-type film 8 of a certain thickness only at the bottom of the recess formed of nitride film 7 (FIG. 3D). Nitride film 7 is then etched away, using the oxide-type film 8 left as a mask (FIG. 3E). At this time, an etching liquid or gas enabling selective etching of the nitride film is utilized. In this case, again, either dry etching or wet etching may be employed.

Polysilicon layer 3 is removed (FIG. 3F). Pad oxide film 2 is removed from the active regions, and thus, a structure formed of isolation film 6 covered with nitride film 7a and oxide-type film 8 is obtained (FIG. 3G). Oxide film 8 on nitride film 7a may be removed where appropriate, so that the above-described structure is completed (FIG. 3H).

With this structure, the effect of preventing the implanted ions from vertically descending the isolation film during the step of forming an element on the active region is improved. This is because the travelling distance, or the range, of the ions in the nitride film is considerably shorter than that in the oxide film. More specifically, in the conventional structure in which a nitride film is not provided on the isolation film, the introduced ions will travel through the isolation film to reach the underlying silicon substrate. Therefore, the isolation film having a sufficient thickness was required. As described above, too thick an isolation film would pose various problems, making adjustment of the film thickness extremely difficult. With the structure of the present embodiment, however, the nitride film is formed on the isolation film, so that the range of the introduced ions is greatly reduced. This prevents the ions from reaching the silicon substrate beneath the isolation film.

Further, in the interconnection step following the element formation step, effective element properties are ensured even in the presence of misalignment of the contact hole. FIG. 2 illustrates such an effect. More specifically, since the protective nitride film is formed on the isolation film, even if misalignment occurs when etching an interlayer insulating film, the protective nitride film prevents the isolation film from being etched. Accordingly, the break of the isolation film is prevented, ensuring effective element properties, and the yield is thus improved.

Second Embodiment

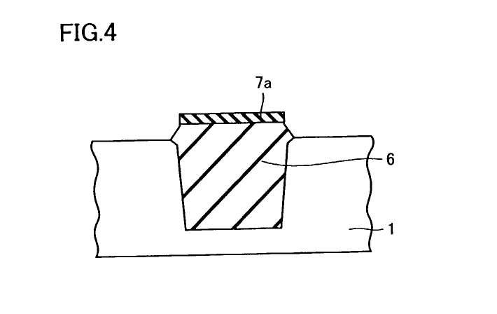

The element isolation structure of a semiconductor device according to the second embodiment will now be described with reference to FIG. 4. In FIG. 4, each component identical to that of the first embodiment is denoted by the same reference character, and therefore, description thereof is not repeated here. In the present embodiment, nitride film 7a on isolation film 6 as in the first embodiment is formed to cover the entire flat surface of isolation film 6.

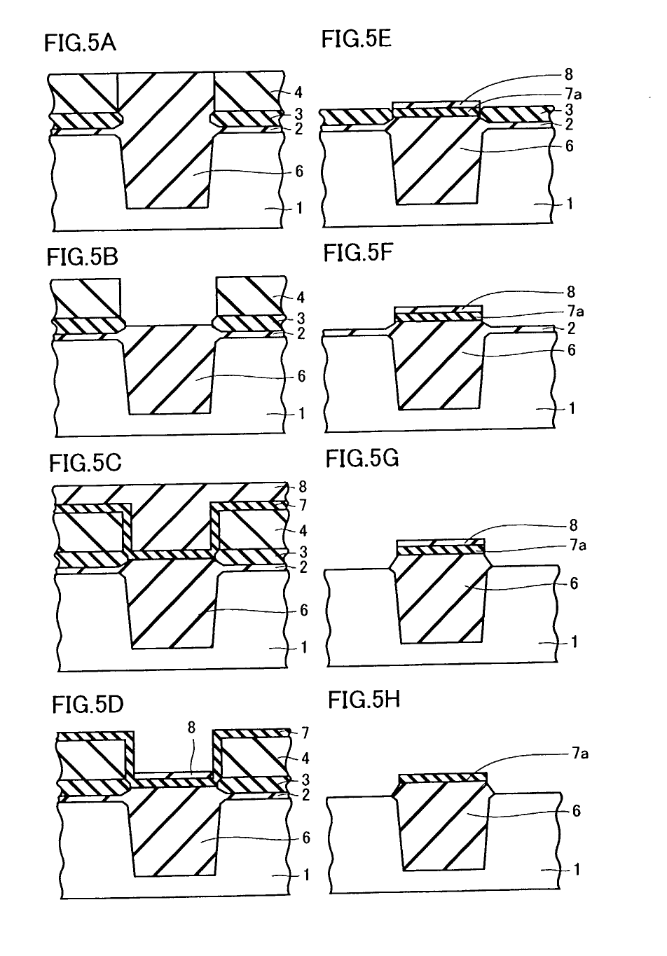

Referring to FIG. 5, the manufacturing method of the semiconductor device having such isolation film and protective nitride film will now be described. In this method, again, the trench is formed employing the conventional technique as described above. Thus, description of the steps illustrated in FIGS. 8A-8E, or up to FIG. 5A, is not repeated here.

In this embodiment, from the state shown in FIG. 5A, buried oxide film 6 is etched, using an etching liquid or gas enabling selective etching of the oxide film, to a level of polysilicon layer 3 (FIG. 5B). In the first embodiment, the etching was controlled not to reach the level of polysilicon layer 3 so as to ensure a distance from the surface of silicon substrate 1 to protective nitride film 7a on isolation film 6. In the second embodiment, oxide film 6 is etched to the level reaching polysilicon layer 3. The following steps illustrated in FIGS. 5C-5H are identical to the corresponding steps of the first embodiment. The semiconductor device having the structure as described above is thus formed.

With such a structure, the effects as in the first embodiment, i.e., preventing travelling of the introduced ions to reach the semiconductor substrate and preventing break of the isolation film due to the misalignment of the contact hole, can be achieved. In particular, according to the present embodiment, it is possible to form the protective nitride film on the isolation film covering a greater area than in the first embodiment. Thus, short-circuit due to the misalignment of the contact can be prevented even if the sidewall of the trench is steeper.

Third Embodiment

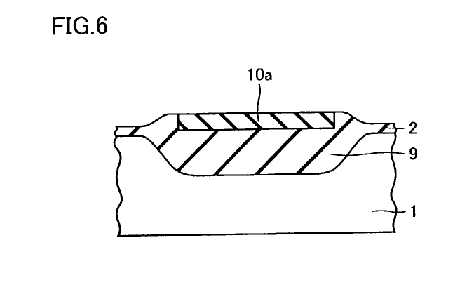

The structure of an isolation film according to the third embodiment will now be described with reference to FIG. 6. The isolation film of the present embodiment is formed by LOCOS. On the surface of silicon substrate 1, a field oxide film 9 as the isolation film is formed by LOCOS, to protrude above the surface of silicon substrate 1. A protective nitride film 10a is formed in a portion of the upper surface of field oxide film 9.

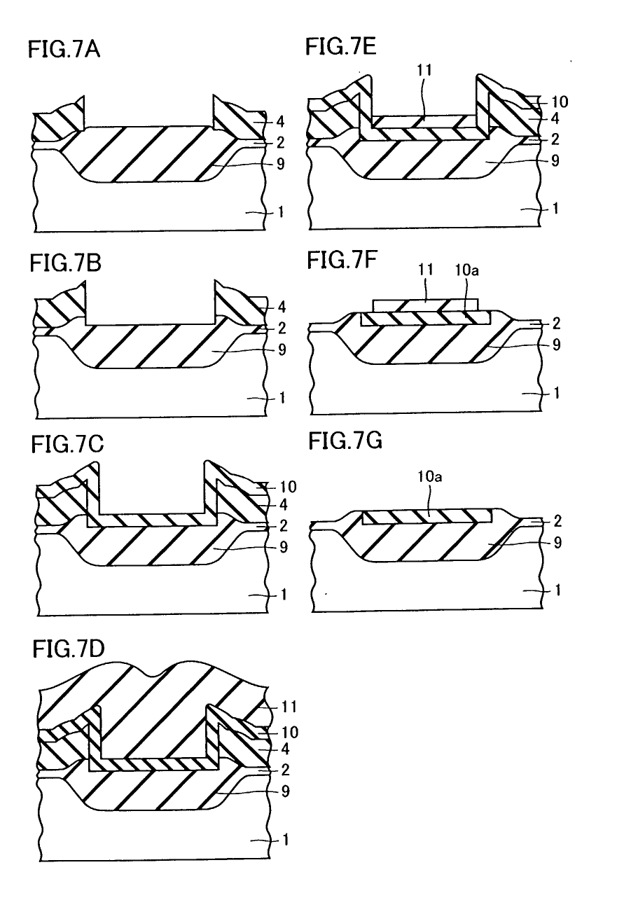

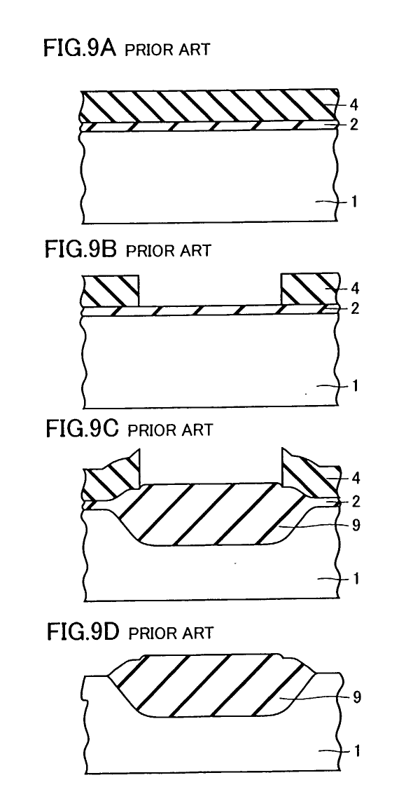

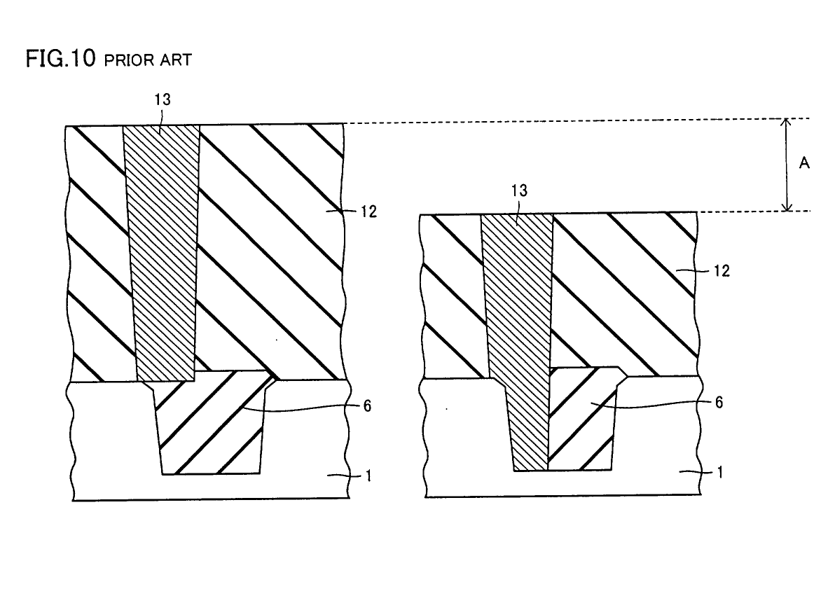

Next, referring to FIGS. 7A-7G, the manufacturing method of the semiconductor device having such isolation film and protective nitride film will be described. The method of the present embodiment adopts the conventional LOCOS process as described above. Thus, description of the respective steps shown in FIGS. 9A-9C, or up to the step shown in FIG. 7A, is not repeated here.

First, from the state shown in FIG. 7A, an upper portion of field oxide film 9 is dry etched, using silicon nitride film 4 as a mask, to form a recess at the upper surface of field oxide film 9 (FIG. 7B). Next, a nitride film 10 is deposited on the semiconductor surface. At this time, nitride film 10 is deposited to a level sufficient enough to fill the recess formed at the upper surface of field oxide film 9 in the preceding step (FIG. 7C).

An oxide-type film 11 is formed on nitride film 10 (FIG. 7D). In this case, all that is needed is that the oxide-type film 11 is formed by at least a prescribed thickness to cover nitride film 10 constituting the bottom surface of the recess. Oxide-type film 11 can be formed, e.g., by high-concentration plasma CVD, TEOS, or any other technique. At this time, heat treatment can be added where appropriate. CMP can be conducted for planarization of the oxide-type film. SOG can be conducted for heat treatment.

Next, oxide-type film 11 is etched away, using an etching liquid or gas that can selectively etch the oxide film, to leave oxide-type film 11 of a prescribed thickness only on the bottom surface of the recess of nitride film 10 (FIG. 7E). Nitride film 10 is then etched, using as a mask the oxide-type film 11 left on the bottom surface of the recess of nitride film 10 (FIG. 7F). The etching liquid or gas used at this time is the one that can selectively etch the nitride film. In this case, again, either dry etching or wet etching may be employed.

Thereafter, pad oxide film 2 left on the active region is removed, so that a structure of field oxide film 9 having its surface covered with protective nitride film 10a can be obtained (FIG. 7G). Here, the oxide-type film 11 may remain on protective nitride film 10a.

By forming the semiconductor device according to the manufacturing method of the present embodiment, it is possible to form the protective nitride film on the isolation film even when the isolation film is being formed by LOCOS. This improves the effect of preventing the introduced ions from reaching the semiconductor substrate during the step of forming an element in the active region, thereby allowing the use of a thinner isolation film. Further, by forming the protective nitride film on the isolation film according to the manufacturing method of the present embodiment, it is possible to form on the field oxide film the nitride film region smaller than in the conventional case. Accordingly, in the semiconductor device like a flash memory wherein a gate electrode is being formed adjacent to this protective nitride film, a sufficient distance is ensured between the gate electrode and the protective nitride film, so that trapping of electrons to the protective nitride film can be prevented. Favorable element properties can thus be realized.

Other Variations of the Embodiments

In the first embodiment described above, the polysilicon layer has been formed between the pad oxide film and the silicon nitride film serving as a mask when etching the trench, such that the upper surface of the isolation film is spaced apart from the surface of the semiconductor substrate. This polysilicon layer is unnecessary in the case where there is no particular need to ensure the space therebetween.

In each embodiment described above, the oxide-type film formed as a mask on the upper surface of the silicon nitride film has been removed. However, the step of removing this oxide-type film may be skipped to leave the film, if it poses no structural problem.

In the manufacturing methods according to the first and second embodiments, isotropic etching of the oxide film may be added, after removal of the silicon nitride film on the active region, so as to remove corners of the isolation film to alleviate the step between the isolation film and the silicon nitride film.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising an element isolation region formed at a main surface of a semiconductor substrate and a silicon nitride film formed on said element isolation region,
said element isolation region having an upper surface protruding above said main surface of said semiconductor substrate, and
said silicon nitride film being positioned, as seen from above, inner than a portion of said element isolation region exposed on said main surface of said semiconductor substrate.

2. The semiconductor device according to claim 1, wherein said element isolation region is formed to fill a trench provided at said main surface of said semiconductor substrate, and said silicon nitride film is positioned, as seen from above, to cover an area of said semiconductor substrate forming a bottom surface of said trench.

3. The semiconductor device according to claim 1, wherein, as seen from above, said silicon nitride film overlaps an element region that is formed adjacent to said element isolation region.
